(19) United States
(12) Patent Application Publication
(10) Pub. No.: US 2011/0291135 A1
(43) Pub. Date: Dec. 1, 2011

(54) LIGHT EMITTING DIODE PACKAGE

(75) Inventors: MIN-TSUN HSIEH, Hukou (TW); WEN-LIANG TSENG, Hukou (TW); LUNG-HSIN CHEN, Hukou (TW); CHIH-YUNG LIN, Hukou (TW)

(73) Assignee: ADVANCED OPTOELECTRONIC TECHNOLOGY, INC., Hsinchu Hsien (TW)

(21) Appl. No.: 13/038,385

(22) Filed: Mar. 2, 2011

(30) Foreign Application Priority Data
Jun. 1, 2010 (CN) 201010188626.1

(51) Int. Cl. H01L 33/58

(52) U.S. Cl. 257/98; 257/E33.068

(57) ABSTRACT

A light emitting diode package includes a silicon substrate having a first surface and a second surface opposite to the first surface, wherein the first surface includes a cavity, a light emitting diode chip fixed on a bottom of the cavity, and a glass lens secured to the silicon substrate and covering the light emitting diode chip.

### BACKGROUND

1. Technical Field

The disclosure relates generally to light emitting diodes, and more particularly to a light emitting diode package with high thermal tolerance.

2. Description of the Related Art

Accompanying increased intensity and luminosity, LED chips generate increased heat to consume than before, especially to high power LED chips. Many plastic leaded chip carriers (PLCCs) cannot tolerate the high temperature, and ceramic materials can experience cracking during sintering and packaging. Therefore, it is desired to provide an LED package which can overcome the described limitations.

### BRIEF DESCRIPTION OF THE DRAWINGS

FIG. 1 is a cross section of a light emitting diode package in accordance with a first embodiment of the disclosure.

FIG. 2 is a view similar to FIG. 1, with a lens being separated from the light emitting diode package.

FIG. 3 is a cross section of the lens of the light emitting diode package in accordance with a second embodiment of the disclosure.

FIG. 4 is a cross section of a light emitting diode package in accordance with a third embodiment of the disclosure.

FIG. 5 is a cross section of a light emitting diode package in accordance with a fourth embodiment of the disclosure.

FIG. 6 is a cross section of a light emitting diode package in accordance with a fifth embodiment of the disclosure.

FIG. 7 is a cross section of a light emitting diode package in accordance with a sixth embodiment of the disclosure.

FIG. 8 is a cross section of a light emitting diode package in accordance with a seventh embodiment of the disclosure.

FIG. 9 is a cross section of a light emitting diode package in accordance with an eighth embodiment of the disclosure.

### DETAILED DESCRIPTION

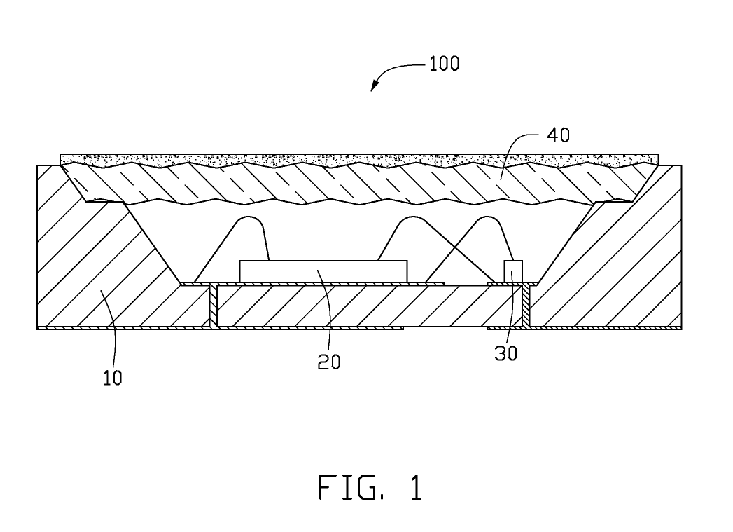

Referring to FIG. 1, it shows a light emitting diode package 100 in accordance with a first embodiment of the disclosure. The light emitting diode package 100 includes a substrate 10, a light emitting diode chip 20, a voltage stabilization diode 30 such as a zener diode, and a lens 40, wherein the light emitting diode chip 20 and the voltage stabilization diode 30 are fixed on the substrate 10, and the lens 40 covers the light emitting diode chip 20 and the voltage stabilization diode 30.

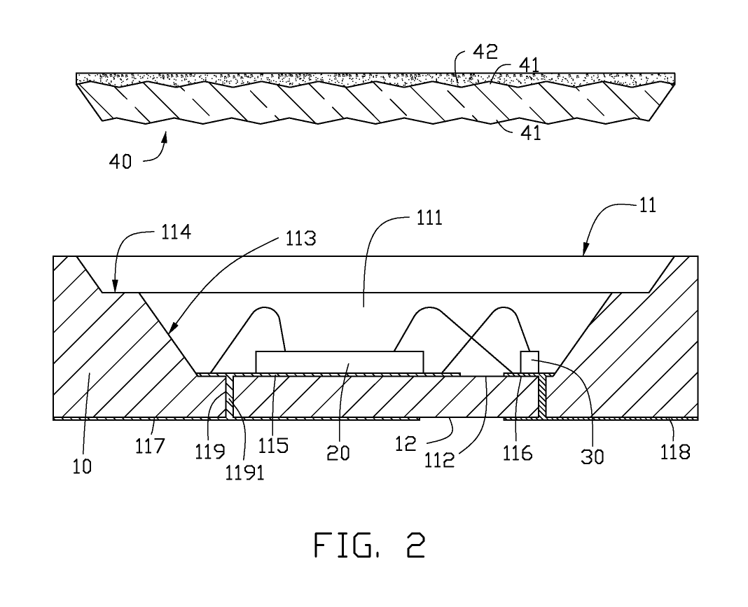

FIG. 2 is a view similar to FIG. 1, with the lens 40 separating from the substrate 10 of the light emitting diode package 100. The substrate 10 is a silicon substrate which has high or low electrical resistance. The silicon substrate 10 with high electrical resistance has an electrical resistivity of about 1 to 30000 Ω/cm and can be doped with boron or phosphor. The silicon substrate 10 with low electrical resistance has an electrical resistivity of about 0.001 to 0.02 Ω/cm and can be doped with boron, phosphor, arsenic, or stibium. In the first embodiment, the silicon substrate 10 has high electrical resistance, including a first surface 11 and a second surface 12 opposite to the first surface 11. The first surface 11 of the silicon substrate 10 has a cavity 111 with a flat bottom 112. Width of the cavity 111 increases along a bottom-to-top direction from the bottom 112 to the first surface 11, so that the sidewall of the cavity 111 forms an inclined reflective wall 113. The angle between the bottom 112 of the cavity 111 and the inclined reflective wall 113 is obtuse, and the inclined reflective wall 113 further comprises a reflective layer thereon to increase reflective efficiency. A platform 114 on the sidewall of the cavity 111 is close to the first surface 11 of the silicon substrate 10, and the bottom of the platform 114 is parallel to the bottom 112 of the cavity 111. The bottom 112 of the cavity 111 defines a first wire bonding area 115 and a second wire bonding area 116, wherein the first wire bonding areal 115 and the second wire bonding area 116 are constructed by conductive materials, such as copper foil, indium titanium oxide, nickel, titanium, silver, aluminum, tin, gold or alloy.

Where the silicon substrate 10 has low electrical resistance, the wire bonding areas 115, 116 and the silicon substrate 10 includes an insulation layer therebetween to avoid short circuit between the two wire bonding areas 115, 116, and the insulation layer can be silicon oxide or silicon nitride.

Moreover, the first wire bonding area 115 is spaced apart from the second wire bonding area 116. The second surface 12 of the silicon substrate 10 defines a first electrode area 117 and a second electrode area 118, wherein the first electrode area 117 and the second electrode area 118 are constructed by conductive materials, such as copper foil, indium titanium oxide, nickel, titanium, silver, aluminum, tin, gold or alloy. The first electrode area 117 and the second electrode area 118 correspond to the first wire bonding area 115 and the second bonding area 116, respectively. The silicon substrate 10 has two through holes 119 through from the bottom 112 thereof to the second surface 12 of the silicon substrate 10, wherein the two through holes are filled by conductive materials, such as copper or silver, to form vias 1191 which electrically connect the first wire bonding area 115 and the first electrode area 117, and the second wire bonding 116 and the second electrode area 118. The light emitting diode chip 20 is fixed on the first wire bonding area 115 in the cavity 111, and connected electrically to the first wire bonding area 115 and the second wire bonding area 116 by gold wires, aluminum wires or silver wires. Alternatively, flip chip connection or eutectic connection can also be applied. In the first embodiment, the light emitting diode chip 20 can be high power chip and generate light of short wavelength less than 450 nm.

The voltage stabilization diode 30 can be a zener diode, fixed on the bottom 112 of the cavity 111 of the silicon substrate 10 and connected electrically to the first wire bonding 115 via a wire and the second wire bonding 116 directly, as shown in FIG. 2. The voltage stabilization diode 30 and the light emitting diode chip 20 are electrically connected together in parallel to stabilize the voltage between the ends of the light emitting diode chip 20.

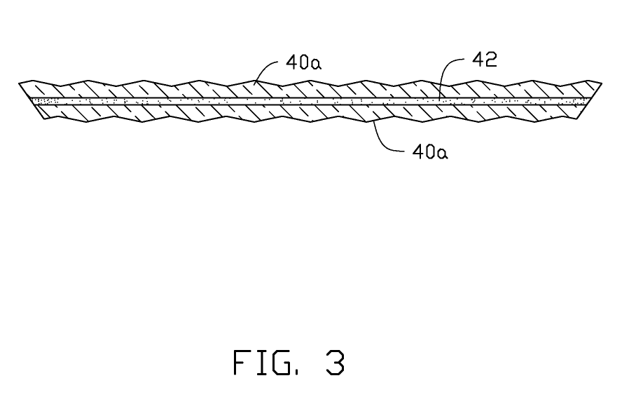

The lens 40 is made of glass, disposed on the platform 114 of the silicon substrate 10 by binder. In the first embodiment, the lens 40 is flat and has microstructures disposed on the surfaces of the lens 40 unevenly, wherein due to the lens 40 having top and bottom surfaces, the microstructures 41 are micro-convex, with those on the top corresponding to those on the bottom, so as to enhance light scattering from the light emitting diode chip 20 and increase interface area between air and lens and remove heat from the light emitting diode package 100. The edge of the lens 40 is as angled corresponding to the sidewall of the cavity 111, allowing firm fit therebetween. Additionally, a fluorescent conversion layer 42 can be coated on the top of the lens 40, such as garnet, silicate, nitride, oxynitride, phosphate, and sulfate. The fluorescent conversion layer 42 can convert light from the light emitting diode 20 and absorbed thereby to another light with different wavelength, so that the light emitting diode package 100 can generate light with multiple wavelengths. The fluorescent conversion layer 42 also can be coated on the bottom of the lens 40, or on both top and bottom of the lens 40, mixed with glass to form a lens, or disposed between two glass layers 40a to form a lens (as shown in FIG. 3).

As disclosed, the silicon substrate 10 and the glass lens 40 optimize thermal tolerance, and the silicon substrate 10 provides maximal thermal conductivity, so that the light emitting diode package 100 exhibits favorable lifetime. Compared with ceramic substrate, the silicon substrate can endure more stress, especially in manufacturing.

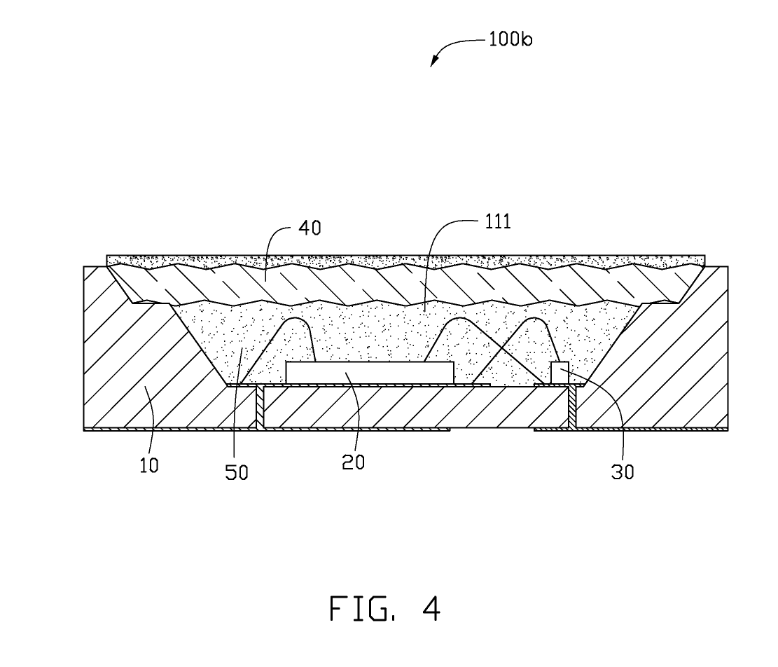

FIG. 4 is a cross section of a light emitting diode package 100b in accordance with a third embodiment of the disclosure. The light emitting diode package 100b has a cavity 111 which is filled by a fluorescent material 50, wherein the fluorescent material 50 is made of a mixture consisting of transparent gel and fluorescent powers. The transparent gel can be silicone, epoxy, or other transparent materials. The fluorescent material 50 not only can convert light from the light emitting diode chip 20 and absorbed thereby to another light having a different wavelength, but also can seal the light emitting diode chip 20 to prevent moisture from environment.

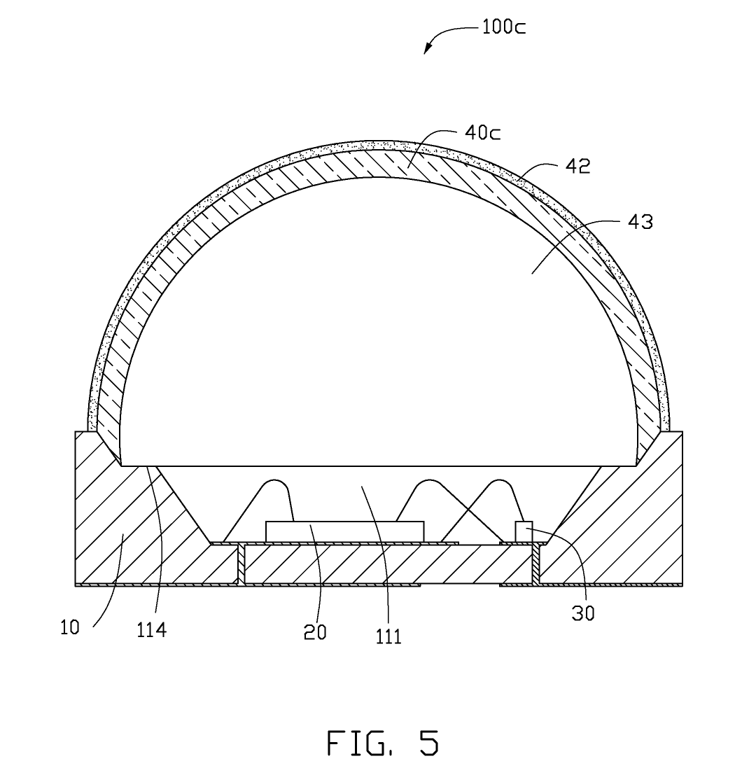

Referring to FIG. 5, it shows a cross section of a light emitting diode package 100c in accordance with a fourth embodiment of the disclosure. The light emitting diode package 100c includes a lens 40c which has an arc-shaped configuration, wherein the lens 40c has concave 43 formed facing to the light emitting diode chip 20. The lens 40c is disposed on the platform 114 of the cavity 111 of the silicon substrate 10. The fluorescent conversion layer 42 can be disposed on a convex, top surface of the lens 40c.

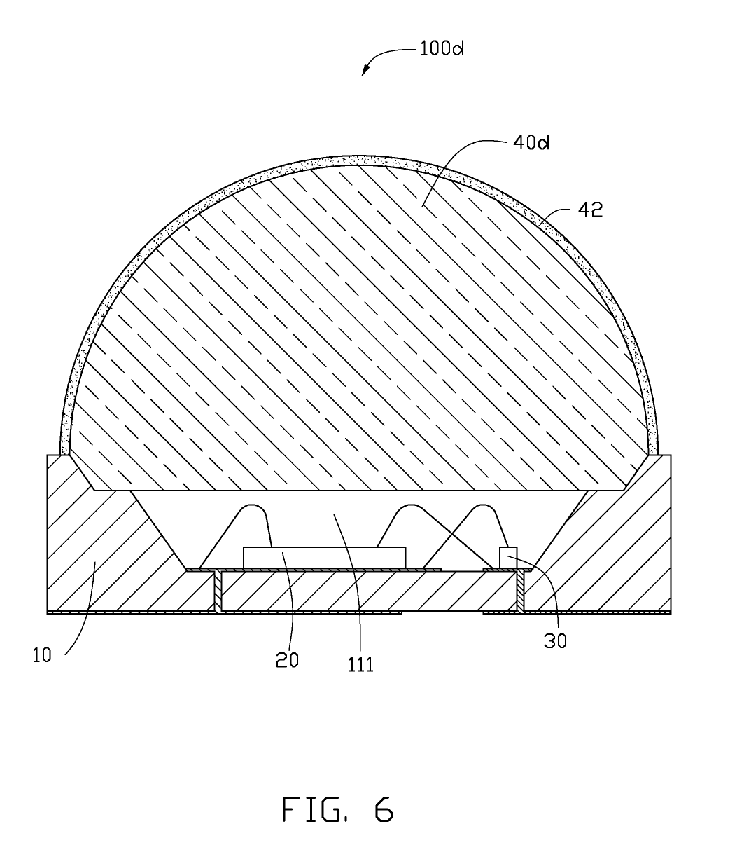

Referring to FIG. 6, it shows a cross section of a light emitting diode package 100d in accordance with a fifth embodiment of the disclosure. The light emitting diode package 100d has a lens 40d which is semicircle, wherein the top of the lens 40d is convex and the bottom of the lens 40d is flat. A fluorescent conversion layer 42 can be disposed on the convex top of the lens 40d.

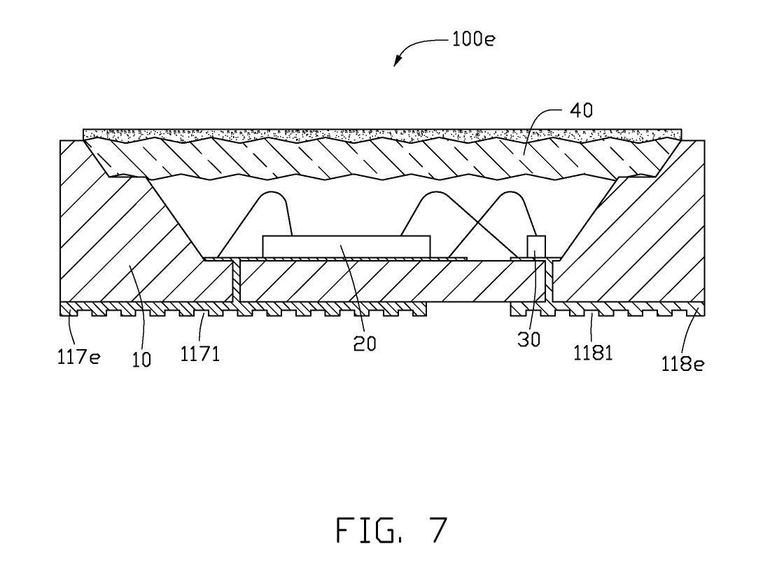

Referring to FIG. 7, it shows a cross section of a light emitting diode package 100e in accordance with a sixth embodiment of the disclosure. The light emitting diode package 100e includes a first electrode area 117e and a second electrode area 118e, wherein the first electrode area 117e and the second electrode area 118e are provided with a plurality of concaves 1171,1181 opposite to the silicon substrate 10. The concaves 1171, 1181 form an uneven surface on the electrode areas 117e, 118e to increase a contact area between the electrode areas 117e, 118e and solder (not shown) interconnecting the electrode areas 117e, 118e and corresponding contact pads of a printed circuit board (not shown) on which the light emitting diode package 100e is mounted, so as to increase the thermal dissipation efficiency of the light emitting diode package 100e, and prevent the solder from spreading to the sidewall of the silicon substrate 10 during the mounting of the light emitting package 100e to the printed circuit board.

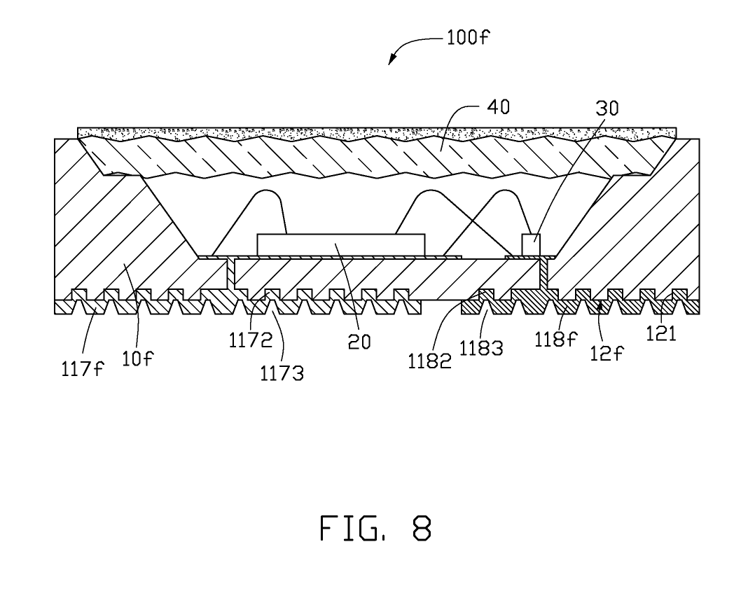

Referring to FIG. 8, it shows a cross section of a light emitting diode package 100f in accordance with a seventh embodiment of the disclosure. In the seventh embodiment, the second surface 12f of the silicon substrate 10f has a plurality of concaves 121, the first electrode area 117f and the second electrode area 118f have a plurality of convexes 1172, 1182 and concaves 1173, 1183, wherein the plurality of convexes 1172, 1182 is disposed on the top of the electrode areas 117f, 118f facing to the second surface 12f of the silicon substrate 10f, and the plurality of concaves 1173, 1183 is disposed on the bottom of the electrode areas 117f, 118f opposite to the plurality of convexes 1172, 1182. The plurality of concaves 121 of the second surface 12f of the silicon substrate 10f and the plurality of convexes 1172, 1182 of the first electrode area 117f and the second electrode area 118f combine to fix together, so as to increase a contact area between the silicon substrate 10f and the electrode areas 117f, 18f to enhance the thermal conductive efficiency from the light emitting diode chip 20 of the light emitting diode package 100f. The plurality of the concaves 1173, 1183 on the bottom of the electrode areas 117f, 118f not only can increase the thermal dissipation efficiency from the light emitting diode package 110f, but also can prevent the solder from spreading to the sidewall of the silicon substrate 10f.

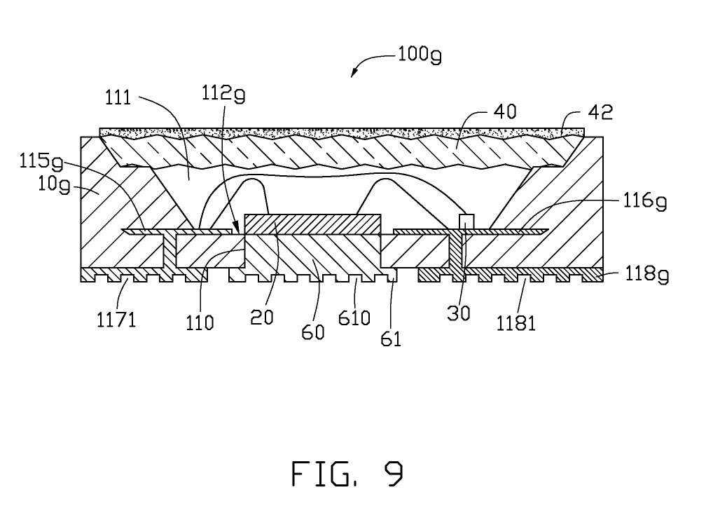

Referring to FIG. 9, it shows a cross section of a light emitting diode package 100g in accordance with an eighth embodiment of the disclosure. In the eighth embodiment, the light emitting diode package 100g has a structure in which conductive paths of heat and electrical current are independent from each other. Furthermore, a through hole 110 is disposed on the bottom 112g of the cavity 111, wherein the through hole 110 is filled a thermal conductive rod 60 which is made of copper, aluminum, or alloy. The first wire bonding area 115g and the second wire bonding area 116g are posited at two sides of the thermal conductive rod 60. The light emitting diode chip 20 is fixed on the thermal conductive rod 60, and connected electrically to the first wire bonding area 115g and the second wire bonding area 116g by metal wires, wherein the heat generated from the light emitting diode chip 20 can dissipate to the environment through the thermal conductive rod 60 directly. The thermal conductive rod 60 has a lower portion 61 projecting downwardly to be out of the silicon substrate 10g of the light emitting diode package 100g. The lower portion 61 has a width and a length larger than those of the thermal conductive rod 60, whereby the lower portion 61 has a shape of a metal plate, wherein the lower portion 61 has a plurality of concaves 610 to increase the dissipation area of the thermal conductive rod 60. Additionally, the first electrode area 117g and the second electrode area 118g have a plurality of concaves 1171, 1181, so as to increase the contact area between the first and second electrode areas 117g, 118g and the solder to thereby prevent the solder from spreading to the sidewall of the silicon substrate 10g.

What is claimed is:

1. A light emitting diode package comprising:
a silicon substrate having a first surface and a second surface opposite to the first surface, wherein the first surface includes a cavity;
a light emitting diode chip fixed on a bottom of the cavity; and
a glass lens secured to the silicon substrate and covering on the light emitting diode chip.

2. The light emitting diode package as claimed in claim 1, wherein the second surface of the silicon substrate has a first electrode area and a second electrode area, and wherein the first electrode area and the second electrode area have a plurality of concaves opposite to the second surface of the silicon substrate.

3. The light emitting diode package as claimed in claim 2, further comprising a plurality of concaves disposed on the second surface of the silicon substrate, a plurality of convexes disposed on tops of the first electrode area and the second electrode area facing to the second surface of the silicon substrate, and wherein the plurality of convexes is engaged in the plurality of concaves to fixedly connect the silicon substrate and the first and second electrode areas together.

4. The light emitting diode package as claimed in claim 1, further comprising a thermal conductive rod in the silicon substrate and separated from the first and second electrode areas, and wherein the light emitting diode chip is fixed on the thermal conductive rod.

5. The light emitting diode package as claimed in claim 4, wherein the thermal conductive rod is copper, aluminum, or alloy.

6. The light emitting diode package as claimed in claim 5, wherein the thermal conductive rod has a bottom portion projecting downwardly to be out of the second surface of the silicon base of the light emitting diode package.

7. The light emitting diode package as claimed in claim 6, wherein the bottom portion of the thermal conductive rod has enlarged width and length to have a plate-shaped configuration, the bottom portion comprising a plurality of concaves in a bottom face thereof.

8. The light emitting diode package as claimed in claim 6, wherein the cavity has a platform, and the glass lens is disposed on the platform of the cavity.

9. The light emitting diode package as claimed in claim 1, wherein the glass lens comprises a plurality of micro-convexes on opposite top and bottom surfaces of the glass lens.

10. The light emitting diode package as claimed in claim 9, wherein the plurality of micro-convexes on the top surface of the glass lens and the plurality of the micro-convexes on the bottom surface of the glass lens are correspondingly located.

11. The light emitting diode package as claimed in claim 1, wherein the glass lens has one of shapes of an arc and a semicircle.

12. The light emitting diode package as claimed in claim 1, wherein the bottom of the cavity has a first wire bonding area and a second wire bonding area, and the second surface of the silicon substrate has a first electrode area and a second electrode area, vias being formed in the silicon substrate and electrically connecting the first bonding area and the first electrode area, and the second bonding area and the second electrode area.

13. The light emitting diode package as claimed in claim 12, wherein the vias are formed by filling through holes defined in the silicon substrate with conductive materials.

14. The light emitting diode package as claimed in claim 12, wherein the light emitting diode chip is fixed on the first wire bonding area and connected electrically to the first wire bonding area and the second wire bonding area by metal wires.
